(19) United States
(12) Patent Application Publication
(10) Pub. No.: US 2026/0358899 A1
(43) Pub. Date: Nov. 12, 2026

(54) ANALOG INPUT DEVICE, COMPUTING SYSTEM AND METHOD FOR RECEIVING AND PROCESSING ANALOG INPUT

(71) Applicant: Razer (ASIA-PACIFIC) PTE LTD., Singapore (SG)

(72) Inventors: Alvin SIM, Singapore (SG); Lionel LIM, Singapore (SG); Kok Kiong LOW, Singapore (SG); ChunTao LUO, Shenzhen (CN); Yajun JIN, Shenzhen (CN)

(73) Assignee: Razer (ASIA-PACIFIC) PTE LTD., Singapore (SG)

(21) Appl. No.: 19/130,618

(22) PCT Filed: Feb. 14, 2023
(86) PCT No.: PCT/CN2023/075997

§ 371 Date: May 16, 2025

(51) Int. Cl. G06F 3/02; H03K 17/94; H03K 17/969

(52) U.S. Cl. CPC G06F 3/0202; H03K 17/943; H03K 17/969; H01H 2239/022

(57) ABSTRACT

In some embodiments, an analog input device includes a mounting panel and a matrix of analog push button assemblies mounted to the mounting panel. Each analog push button assembly includes an analog pressure sensor that includes a plunger element and a pressure reception arrangement having an optical sensing sub-arrangement and an output terminal. When the analog push button assembly is pressed by a user's finger, the plunger element is configured to move towards the mounting panel to exert a pressure on the pressure reception arrangement. The optical sensing sub-arrangement includes a light blocking element which is associated with the plunger element so as to be movable together with the plunger element along a movement direction of the plunger element, and the light blocking element includes a cut-out profile which varies an amount of light passing through the light blocking element as the light blocking element moves along the movement direction.

### TECHNICAL FIELD

Various embodiments generally relate to an analog input device. In particular, various embodiments generally relate to a force-sensitive or pressure sensitive analog input device.

### BACKGROUND

Conventionally, input devices such as gaming controller, gaming keypad, keyboard, or mice includes buttons or keys which are coupled to digital switches. These digital switches only output binary signal, and limits the achievable functions of the input devices and possible user intents. For example, in gaming, more granularity of the input may be preferred for more precise control of a magnitude for a character's speed, directions, movements, actions etc. Such controls are typically not achievable with binary input devices.

Accordingly, there is a need for a more effective input device to address the above issues.

### SUMMARY

According to various embodiments, there is provided an analog input device. The analog input device may include a mounting panel; a matrix of analog push button assemblies mounted to the mounting panel, each analog push button assembly comprising an analog pressure sensor, wherein the analog pressure sensor comprises: a plunger element; and a pressure reception arrangement having an optical sensing sub-arrangement and an output terminal, wherein when the analog push button assembly is pressed by a user's finger, the plunger element is configured to move towards the mounting panel to exert a pressure on the pressure reception arrangement, wherein the optical sensing sub-arrangement comprises a light blocking element which is associated with the plunger element in a manner so as to be movable together with the plunger element along a movement direction of the plunger element, and the light blocking element comprises a cut-out profile which varies an amount of light passing through the light blocking element as the light blocking element moves along the movement direction, and wherein the pressure reception arrangement is configured to measure the amount of light passing through the light blocking element and output an analog signal corresponding to the amount of light measured through the output terminal.

According to various embodiments, there is provided a computing system for receiving and processing analog input. The computing system may include a host processor; and the input device according to various embodiments connected to the host processor via a communication interface, wherein the host processor is configured to receive a data packet from the input device, to determine an amount of depression of a respective push button assembly based on a digital-step-value corresponding to the analog signal from the push button assembly, and to generate a corresponding predetermined application event in an application based on the determined amount of depression of the respective push button assembly and an input setting for the application.

According to various embodiments, there is provided a method of processing analog input for a computing system according to various embodiments. The method may include: generating, via the pressure reception arrangement, the analog signal corresponding to the amount of light measured as a measure of the pressure exerted on the pressure reception arrangement when the push button assembly is pressed by a user's finger; digitizing, via the analog-to-digital converter, the analog signal into the corresponding digital-step-value; outputting, via the processor, the data packet including a button identity (ID) of the push button assembly pressed by the user's finger and a digital-step-value corresponding to the analog signal from the push button assembly; transmitting, via the communication interface, the data packet from the processor of the input device to the host processor of the computing system; determining, via the host processor, the amount of depression of the respective push button assembly based on the corresponding digital-step-value from the data packet received; and generating, via the host processor, the corresponding predetermined application event in the application based on the determined amount of depression of the respective push button assembly and the input setting for the application.

According to various embodiments, there is provided a calibration system. The calibration system may include: a calibration fixture; a calibration computer program stored in a host computing device; and a firmware programmed to the analog input device according to various embodiments, the calibration system further comprising one or more processors; and memory storing instructions that, when executed by the one or more processors, cause the calibration system to: (i) send, by the calibration computer program, commands to drive the calibration fixture to press an analog push button assembly of the matrix of analog push button assemblies to a bottom position of the analog push button assembly; (ii) send, by the calibration computer program, parameters and commands to the firmware to start calibration; (iii) adjust, by the firmware, Infrared (IR) current and IR active time until sampling values meet a first threshold for the bottom position of the analog push button assembly; (iv) calculate, by the firmware, an average and range of the sampling values for the bottom position of the analog push button assembly, and send the average and range of the sampling values for the bottom position of the analog push button assembly to the calibration computer program; (v) send, by the calibration computer program, a pass to the firmware if the average and range of the sampling values for the bottom position of the analog push button assembly meet a second threshold for the bottom position of the analog push button assembly; and (vi) save, by the calibration computer program, the average and range of the sampling values as a benchmark value for the bottom position of the analog push button assembly.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1 shows a schematic diagram of an example analog input device according to various embodiments;

FIG. 2A shows an example cut-out profile of a light blocking element of the example analog input device of FIG. 1 according to various embodiments; FIG. 2B and FIG. 2C show example movements of the cut-out profile of the light blocking element of the example analog input device of FIG. 1 according to various embodiments;

FIG. 3A shows a schematic diagram of an example analog input device according to various embodiments; FIG. 3B shows a graph of voltage changes with travel distances of a light blocking element of the example computing system with the analog input device of FIG. 3A according to various embodiments;

FIG. 4 shows a schematic diagram of an example computing system for receiving and processing analog input according to various embodiments;

FIG. 5 shows a schematic diagram of an example computing system with an analog keypad as an input device according to an example embodiment;

FIG. 6 shows a calibration system implemented by the input devices according to various embodiments; and

FIG. 7 shows a flowchart of the user calibration process of the input devices according to various embodiments.

### DETAILED DESCRIPTION

Embodiments described below in the context of the apparatus are analogously valid for the respective methods, and vice versa. Furthermore, it will be understood that the embodiments described below may be combined, for example, a part of one embodiment may be combined with a part of another embodiment.

It should be understood that the terms “on”, “over”, “top”, “bottom”, “down”, “side”, “back”, “left”, “right”, “front”, “lateral”, “side”, “up”, “down” etc., when used in the following description are used for convenience and to aid understanding of relative positions or directions, and not intended to limit the orientation of any device, or structure or any part of any device or structure. In addition, the singular terms “a”, “an”, and “the” include plural references unless context clearly indicates otherwise. Similarly, the word “or” is intended to include “and” unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the embodiment for an application for which it is intended. In some instances, the approximating language may correspond to the precision of an instrument for measuring the value.

As used herein, the phrase of the form of “at least one of A or B” may include A or B or both A and B. Correspondingly, the phrase of the form of “at least one of A or B or C”, or including further listed items, may include any and all combinations of one or more of the associated listed items.

As described herein, a processor (or a processing unit or a host processing unit or a host processor etc) may be understood as any kind of a logic implementing entity, which may be special purpose circuitry or a processor executing software stored in a memory, firmware, or any combination thereof. Thus, the processor may be a hard-wired logic circuit or a programmable logic circuit such as a programmable processor (e.g. Programmable Logic Controller (PLC)), e.g. a microprocessor (e.g. a Complex Instruction Set Computer (CISC) processor or a Reduced Instruction Set Computer (RISC) processor). The processor may also be a processor executing software, e.g. any kind of computer program, e.g. a computer program using a virtual machine code such as e.g. Java.

Various embodiments generally relate to an analog input device. In particular, various embodiments generally relate to a force-sensitive analog input device or a pressure-sensitive analog input device. According to various embodiments, the input device may include, but not limited to, a controller, a keypad, a keyboard, a mouse, a joystick, or a steering wheel. According to various embodiments, the input device may include a matrix of analog buttons or keys, each may be configured to vary an input signal based on an amount of depressing force or pressure applied by a user on the respective analog button or key. Accordingly, the respective analog button or key may provide a variable force-sensitive or pressure-sensitive analog input depending on the force or pressure applied to the analog button or key. According to various embodiments, varying an amount of depressing force or pressure applied on the respective analog button or key may vary an extent or magnitude of depression experienced by the analog button or key. Accordingly, varying the extent or magnitude of depression of the respective analog button or key may vary an analog output signal of the respective analog button or key from the analog input device. For example, the amount of depressing force or pressure applied on the respective analog button or key may be in proportion to the analog output signal of the respective analog button or key from the analog input device. Specifically, the amount of depressing force or pressure applied on the respective analog button or key may be in linear proportion to the analog output signal of the respective analog button or key from the analog input device. According to various embodiments, the analog output signal may be processed by a processor to generate a corresponding application event in an application.

In some aspects of what is described here, the proposed analog input device may include a light blocking element which is associated with the respective analog button or key in a manner so as to be movable together with the the respective analog button or key along a movement direction of the respective analog button or key. The light blocking element may include a cut-out profile which varies an amount of light passing through the light blocking element as the light blocking element moves along the movement direction. Specifically, when the analog button or key is not pressed and the light blocking element is at the initial position, the light blocking element may allow an initial amount of light to pass through the blocking element. This may mean that when the analog button or key is pressed, the analog output signal (e. g. analogy voltage) does not start from zero but a positive number; as the analog button or key travels along the movement direction, the analog output signal may increase from the positive number, thereby resulting a smooth increase (e. g. not abrupt from zero) of the analog output signal. Therefore, a linear increase of the analog output signal with respect to the travel distance of the analog button or key may be obtained.

According to some aspects, the proposed input device may include digital potentiometers having a tunable resistance. Each analogy button or key may be in electrical connection with one digital potentiometer and the analog output signal may be adjusted by the digital potentiometer in a manner that a linear increase of the analog output signal with respect to the travel distance of the analog button or key may be obtained. The digital potentiometers may be calibrated by software commands and therefore a software program (e.g. executed by a processor) may be used to control the digital potentiometers. Although the digital potentiometer is used in the present various embodiments, it should be appreciated any other electrical component (e.g. a rheostat) having tunable resistance may be employed and replace the digital potentiometer.

In some instances, aspects of the systems and techniques described here provide technical improvements and advantages over existing approaches. For example, the proposed analogy input device provides analog switches with analog output (e.g. input to the host device). This may mean that a different travel distance may correspond to a different analog output signal and consequently a different input at the host device (e.g. in terms of magnitudes, e.g. to activate different functions in an application running on the host device). The analog output may be adjusted by the digital potentiometers (e.g. after pre-calibration in the factory through a software program and calibration by the user as described herein) to be linearly proportional to the travel distance of the analog buttons or keys. For example, a fully pressed analog button or key (i.e. at the maximum travel distance) may correspond to e.g. move a predetermined distance of a character (e.g. an avatar) in a game; a half pressed analog button or key (i.e. at ½ of the maximum travel distance) may correspond to e.g. move the character halfway of the predetermined distance, and a quarterly pressed analog button or key (i.e. at ¼ of the maximum travel distance) may correspond to e.g. move the character a quarter of the predetermined distance; and so forth. In other words, by pressing the analog button or key to a partial (e.g. including, but not limited to, part, fraction) of the maximum travel distance, the user may provide an input with a controlled magnitude (e.g. scale, extent) which in turn corresponds to a distinctive command in the host device. Further, the controlled magnitude (e.g. scale, extent) may be continuous with respect to the travel distance of the analog button or key.

Various embodiments generally relate to a computing system for receiving and processing analog input and a method of processing analog input for the computer system. The computing system may refer to an information handling system or a functional system capable of performing substantial computation. The computing system may include a processing unit, random-access memory, disk storage, input and output devices etc. According to various embodiments, the computing system may include a host processor and the analog input device of the various embodiments. According to various embodiments, the user may provide an analog input via the analog input device such that an analog input signal may be sent via the analog input device to the host processor and the host processor may process the analog input signal to generate a corresponding application event in response to the analogy input signal and provide a corresponding output. The corresponding output may include, but not limited to, a text and/or graphic display, sound, lightings, or haptic feedback.

The following examples pertain to various embodiments.

Example 1 is an analog input device including: a mounting panel; a matrix of analog push button assemblies mounted to the mounting panel, each analog push button assembly comprising an analog pressure sensor, wherein the analog pressure sensor comprises: a plunger element; and a pressure reception arrangement having an optical sensing sub-arrangement and an output terminal, wherein when the analog push button assembly is pressed by a user's finger, the plunger element is configured to move towards the mounting panel to exert a pressure on the pressure reception arrangement, wherein the optical sensing sub-arrangement comprises a light blocking element which is associated with the plunger element in a manner so as to be movable together with the plunger element along a movement direction of the plunger element, and the light blocking element comprises a cut-out profile which varies an amount of light passing through the light blocking element as the light blocking element moves along the movement direction, and wherein the pressure reception arrangement is configured to measure the amount of light passing through the light blocking element and output an analog signal corresponding to the amount of light measured through the output terminal.

In Example 2, the subject matter of Example 1 may optionally include that the light blocking element is configured to move from an initial position to a maximum position along the movement direction together with the plunger element corresponding to the depression of the push button assembly by the user's finger.

In Example 3, the subject matter of Example 2 may optionally include that when the analog push button assembly is not pressed and the light blocking element is at the initial position, the light blocking element allows an initial amount of light to pass through the blocking element.

In Example 4, the subject matter of Example 3 may optionally include that the light blocking element comprises a cut-out portion, and the cut-out portion has an elongate shape extending from a lower end to an upper end of the light blocking element and enclosed by a continuous border.

In Example 5, the subject matter of Example 4 may optionally include that a width between opposing borders of the cut-out portion along a direction perpendicular to the movement direction of the plunger element gradually increases from the lower end to the upper end of the light blocking element in a manner that the amount of light passing through the light blocking element increases as the light blocking element moves along the movement direction from the initial position to the maximum position.

In Example 6, the subject matter of Example 5 may optionally include that the width between opposing borders of the cut-out portion gradually increases in a manner that the amount of light passing through the light blocking element increases linearly.

In Example 7, the subject matter of Example 5 may optionally include that when the light blocking element moves from the initial position to the maximum position, the width between opposing borders of the cut-out portion increases from an initial width allowing the initial amount of light passing through the blocking element to a maximum width.

In Example 8, the subject matter of Example 2 may optionally include that a travel distance of the light blocking element between the initial position to the maximum position is equal to or greater than 4 mm.

In Example 9, the subject matter of Example 1 may optionally include that the optical sensing sub-arrangement further comprises: a light emitter oriented to emit light along a light path perpendicular to the movement direction; and a light sensor which is disposed in the light path and which is configured to generate the analog signal based on the amount of light sensed by the light sensor for outputting via the output terminal, wherein the light blocking element moves transversely across the light path when the plunger element is moved towards the mounting panel.

In Example 10, the subject matter of Example 9 may optionally include that the amount of light sensed by the light sensor for outputting via the output terminal is below a saturation value of the light sensor.

In Example 11, the subject matter of Example 1 may optionally include a digital potentiometer, wherein the digital potentiometer is coupled in electrical connection with the matrix of analog push button assemblies and tunable with respect to its resistance.

In Example 12, the subject matter of Example 11 may optionally include that the analog signal is an analog voltage.

In Example 13, the subject matter of Example 12 may optionally include that the analog voltage is in inverse proportion with the amount of light passing through the light blocking element.

In Example 14, the subject matter of Example 12 may optionally include that the digital potentiometer is tunable in a manner that the analog voltage is linearly proportional to a travel distance of the light blocking element.

In Example 15, the subject matter of Example 1 may optionally include a multiplexer including an input side and an output side, wherein the input side is coupled to the output terminals of the matrix of analog push button assemblies; an analog-to-digital converter which is coupled to the output side of the multiplexer; a processor which is coupled to the analog-to-digital converter and which is configured to output a data packet including a button identity (ID) of the push button assembly pressed by the user's finger and a digital-step-value corresponding to the analog signal from the push button assembly; and a communication interface configured to transmit the data packet to a host computing device.

In Example 16, the subject matter of Example 15 may optionally include an analog filter coupled in an electrical connection between the pressure sensor and the analog-to-digital converter.

In Example 17, the subject matter of Example 15 may optionally include a lighting arrangement including at least one light source controlled by the processor.

In Example 18, the subject matter of Example 1 may optionally include that the pressure reception arrangement comprises a biasing element which is arranged between the plunger element and the mounting panel and which biases the plunger element away from the mounting panel in a biasing direction.

Example 19 is a computing system for receiving and processing analog input, the computing system including: a host processor; and the input device according to any one of Examples 1 to 18 connected to the host processor via a communication interface, wherein the host processor is configured to receive a data packet from the input device, to determine an amount of depression of a respective push button assembly based on a digital-step-value corresponding to the analog signal from the push button assembly, and to generate a corresponding predetermined application event in an application based on the determined amount of depression of the respective push button assembly and an input setting for the application.

In Example 20, the subject matter of Example 19 may optionally include that the host processor is further configured to transform the determined amount of depression onto a non-linear scale prior to generating the corresponding predetermined application event.

In Example 21, the subject matter of Example 19 may optionally include that the corresponding predetermined application event comprises a continuous variable action, and wherein the host processor is configured to generate a state of the continuous variable action according to the determined amount of depression.

In Example 22, the subject matter of Example 19 may optionally include that the corresponding predetermined application event comprises a discrete action, and wherein the host processor is configured to generate the discrete action when the determined amount of depression is equal to or greater than a pre-set depression level.

In Example 23, the subject matter of Example 19 may optionally include that the corresponding predetermined application event comprises a first discrete action and a second discrete action, and wherein the host processor is configured to generate the first discrete action when the determined amount of depression is equal to a first pre-set depression level or between the first pre-set depression level and a second pre-set depression level, and to generate the second discrete action when the determined amount of depression is equal to or greater than the second pre-set depression level.

In Example 24, the subject matter of Example 19 may optionally include that the host processor is configured to toggle between a first input setting and a second input setting for the application based on a user input command via a physical modifier key or a virtual modifier key, and wherein a first corresponding predetermined application event associated with the first input setting is different from a second corresponding predetermined application event associated with the second input setting.

Example 25 is a method of processing analog input for a computing system according to Example 19, the method include: generating, via the pressure reception arrangement, the analog signal corresponding to the amount of light measured as a measure of the pressure exerted on the pressure reception arrangement when the push button assembly is pressed by a user's finger; digitizing, via the analog-to-digital converter, the analog signal into the corresponding digital-step-value; outputting, via the processor, the data packet including a button identity (ID) of the push button assembly pressed by the user's finger and a digital-step-value corresponding to the analog signal from the push button assembly; transmitting, via the communication interface, the data packet from the processor of the input device to the host processor of the computing system; determining, via the host processor, the amount of depression of the respective push button assembly based on the corresponding digital-step-value from the data packet received; and generating, via the host processor, the corresponding predetermined application event in the application based on the determined amount of depression of the respective push button assembly and the input setting for the application.

In Example 26, the subject matter of Example 25 when depending on Example 14 may optionally include calibrating the tunable digital potentiometer, via the processor, by pressing the analog push button assembly until the light blocking element reaches a maximum position.

In Example 27, the subject matter of Example 25 may optionally include transforming the determined amount of depression onto a non-linear scale prior to generating the corresponding predetermined application event.

In Example 28, the subject matter of Example 25 may optionally include that the corresponding predetermined application event comprises a continuous variable action, and wherein generating the corresponding predetermined event comprises generating a state of the continuous variable action according to the determined amount of depression.

In Example 29, the subject matter of Example 25 may optionally include that the corresponding predetermined application event comprises a discrete action, and wherein generating the corresponding predetermined event comprises generating the discrete action when the determined amount of depression is equal to or greater than a pre-set depression level.

In Example 30, the subject matter of Example 25 may optionally include that the corresponding predetermined application event comprises a first discrete action and a second discrete action, and wherein generating the corresponding predetermined event comprises generating the first discrete action when the determined amount of depression is equal to a first pre-set depression level or between the first pre-set depression level and a second pre-set depression level, and to generate the second discrete action when the determined amount of depression is equal to or greater than the second pre-set depression level.

In Example 31, the subject matter of Example 25 may optionally include toggling between a first input setting and a second input setting for the application based on a user input command via a physical modifier key or a virtual modifier key, and wherein a first corresponding predetermined application event associated with the first input setting is different from a second corresponding predetermined application event associated with the second input setting.

Example 32 is a calibration system including: a calibration fixture; a calibration computer program stored in a host computing device; and a firmware programmed to the analog input device of Example 1, the calibration system further comprising one or more processors; and memory storing instructions that, when executed by the one or more processors, cause the calibration system to: (i) send, by the calibration computer program, commands to drive the calibration fixture to press an analog push button assembly of the matrix of analog push button assemblies to a bottom position of the analog push button assembly; (ii) send, by the calibration computer program, parameters and commands to the firmware to start calibration; (iii) adjust, by the firmware, Infrared (IR) current and IR active time until sampling values meet a first threshold for the bottom position of the analog push button assembly; (iv) calculate, by the firmware, an average and range of the sampling values for the bottom position of the analog push button assembly, and send the average and range of the sampling values for the bottom position of the analog push button assembly to the calibration computer program; (v) send, by the calibration computer program, a pass to the firmware if the average and range of the sampling values for the bottom position of the analog push button assembly meet a second threshold for the bottom position of the analog push button assembly; and (vi) save, by the calibration computer program, the average and range of the sampling values as a benchmark value for the bottom position of the analog push button assembly.

In Example 33, the subject matter of Example 32 may optionally include repeating the steps (i) to (vi) for a middle position of the analog push button assembly and a top position of the analog push button assembly.

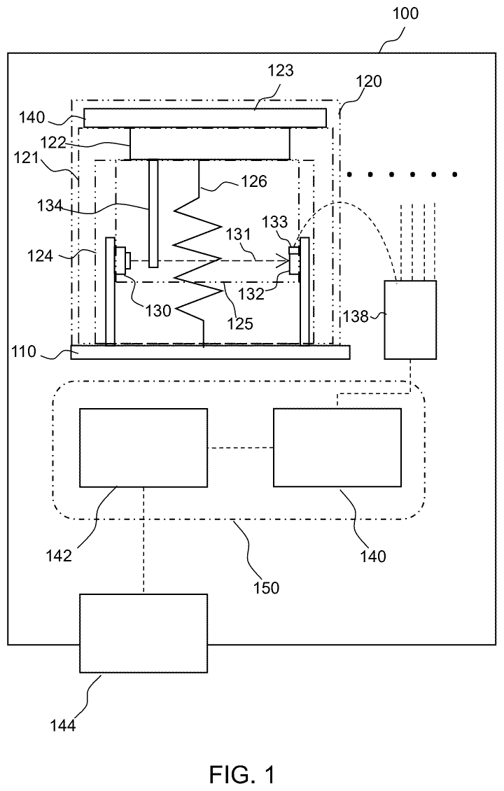

FIG. 1 shows a schematic diagram of an analog input device 100 according to various embodiments. According to various embodiments, the analog input device 100 may include at least one mounting panel 110. According to various embodiments, the at least one mounting panel 110 may be part of an internal support structure of the analog input device 100. According to various embodiments, the at least one mounting panel 110 may also be an internal printed circuit board (PCB) of the analog input device 100. According to various embodiments, the analog input device 100 may include a matrix of analog push button assemblies 120 mounted to the at least one mounting panel 110. According to various embodiments, the analog input device 100 may include two or more or a plurality of analog input button assemblies 120. For example, when the analog input device 100 is a mouse, the analogy input device 100 may include two or more analog click buttons. When the analog input device 100 is a keypad having 15-25 keys, the analog input device 100 may include up to 15-25 analog keys. When the analog input device 100 is a gaming controller having four or more buttons, the analog input device 100 may include two or three or four or more analog buttons. When the analog input device 100 is a keyboard, the analog input device 100 may include a plurality of analog keys.

According to various embodiments, each analog push button assembly 120 may include a pressure sensor 121 having a plunger element 122 and a pressure reception arrangement 124. The plunger element 122 may interact with the pressure reception arrangement 124 in a manner so as to exert a pressure or a force on the pressure reception arrangement 124 when the analog push button assembly 120 is being pressed by a user's finger. Specifically, when the analog push button assembly 120 is being pressed by a user's finger, the plunger element 122 may be configured to move towards the mounting panel 110 to exert a pressure on the pressure reception arrangement 124. According to various embodiments, the pressure sensor 121 may be a swappable single unitary key-switch or may be a non-separable integrated built-in arrangement of the analog input device 100. According to various embodiments, each analog push button assembly 120 may include a button cap 123 removably coupled or fixedly coupled to the plunger element 122 of the pressure sensor 121. According to various embodiments, the button cap 123 may be a thin shell having an input surface for receiving a fingertip of the user. The button cap 123 may be ergonomically shaped for receiving the fingertip. Accordingly, the plunger element 122 may move in a movement direction of the plunger element 122 together with the button cap 123 when the button cap 123 is being pressed by the user's finger. The movement direction of the plunger element 122 may be perpendicular to a plane of the mounting panel 110.

According to various embodiments, the pressure reception arrangement 124 of each analog push button assembly 120 may include an optical sensing sub-arrangement 125 configured to measure an amount of light varied according to a pressure or force sensed at the pressure reception arrangement 124. Accordingly, depressing the push button assembly 120 may exert a corresponding pressure or force on the pressure reception arrangement 124 which may vary the amount of light sensed by the optical sensing sub-arrangement 125. According to various embodiments, the amount of light may be varied via proportionally varying an extent of blockage of the light with a light blocking element 134 with respect to the pressure or force on the pressure reception arrangement 124. According to various embodiments, the pressure reception arrangement 124 may include an output terminal 133 for outputting an analog signal corresponding to the amount of light measured. Accordingly, the amount of light measured may be output as the analog signal. According to various embodiments, the amount of light may be an intensity of light.

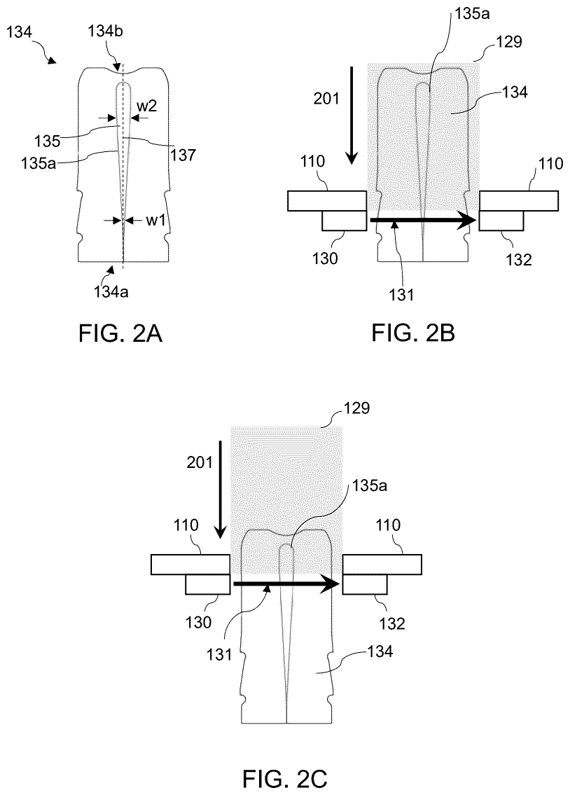

According to various embodiments, the pressure reception arrangement 124 may include a biasing element 126. The biasing element 126 may be arranged between the plunger element 122 and the at least one mounting panel 110. The biasing element 126 may bias the plunger element 122 away from the at least one mounting panel 110 in a biasing direction. Accordingly, the biasing element 126 may provide resistance against the pressure or force depressing the analog push button assembly 120. The biasing direction may be parallel to the movement direction of the plunger element 122. According to various embodiments, the biasing element 126 may include a spring or a resilient membrane structure or other suitable elements, structures or configurations which may return the plunger element 122 to an original or initial position after being depressed. According to various embodiments, the biasing element 126 may be directly or indirectly connected in between the plunger element 122 and the at least one mounting panel 110. According to various embodiments, the pressure reception arrangement 124 may include a housing (e. g. 129 in FIGS. 2B and 2C) mounted to the at least one mounting panel 110 and the plunger element 122 may be slidable through a ceiling of the housing. The button cap 123 may be coupled to the plunger element 122 so as to be movable relative to the housing. The biasing element 126 may bias the plunger element 122 away from the floor of the housing in the biasing direction so as to indirectly bias the button cap 123 away from the at least one mounting panel 110.

According to various embodiments, the optical sensing sub-arrangement 125 of the pressure reception arrangement 124 may include a light emitter 130. The light emitter 130 may be disposed at an intermediate level between the plunger element 122 and the at least one mounting panel 110. The light emitter 130 may be oriented to emit light along a light path 131 non-parallel to the movement direction of the plunger element 122 (e.g. or the biasing direction of the biasing element 126). Specifically, the light emitter 130 may be oriented to emit light along a light path 131 perpendicular to the movement direction of the plunger element 122 (e.g. or the biasing direction of the biasing element 126). Accordingly, the light path 131 of the light emitted from the light emitter 130 may be substantially perpendicular to a direction of depression of the at least one analog input button assembly 120 by the user. According to various embodiments, the light emitter 130 may be a laser light emitter or a collimated light emitter. According to various embodiments, the intermediate level between the plunger element 122 and the at least one mounting panel 110 may be a position along a height between the mounting panel 110 and a maximum depression of the plunger element 122.

According to various embodiments, the optical sensing sub-arrangement 125 of the pressure reception arrangement 124 may include a light sensor 132. The light sensor 132 may be disposed in the light path 131 and may be configured to output an analog signal based on the amount of light sensed by the light sensor 132 for outputting via the output terminal 133. Accordingly, the light sensor 132 may be placed in a position that is directly facing the light emitter 130. Hence, the light emitter 130 and the light sensor 132 may be arranged in an opposing manner such that the light from the light emitter 130 is directly projected straight towards the light sensor 132. According to various embodiments, the light sensor 132 may detect an intensity of light incident on the light sensor 132 and output an analog signal according to the intensity of light detected. According to various embodiments, the light sensor 132 may include, but not limited to, a phototransistor-type light sensor or a photoresistor-type light sensor or a photodiode-type light sensor. According to various embodiments, the analog signal from the light sensor 132 may be an analog voltage or an analog current.

According to various embodiments, the optical sensing sub-arrangement 125 of the pressure reception arrangement 124 may include a light blocking element 134. The light blocking element 134 may be associated with the plunger element 122 in a manner so as to be movable together with the plunger element 122 along the movement direction of the plunger element 122 (e. g. parallel to the biasing direction of the biasing element 126). The light blocking element 134 may be extending towards the mounting panel 110 to intersect the light path 131 between the light emitter 130 and the light sensor 132. According to various embodiments, the light blocking element 134 may be directly or indirectly coupled to the plunger element 122. According to various embodiments, the light blocking element 134 may be of an elongate shape and may be extending downwards towards the mounting panel 110. According to various embodiments, the light blocking element 134 may be positioned in a manner such that a movement path of the light blocking element 134, due to depressing of the analog push button assembly 120 by the user, may intersect the light path 131 between the light emitter 130 and the light sensor 132. According to various embodiments, when the pressure reception arrangement 124 includes the housing and the plunger element 122 is slidable through the ceiling of the housing with the button cap 123 coupled to the plunger element 122, the light blocking element 134 may be coupled to the plunger element 122 so as to be movable together with the button cap 123.

According to various embodiments, the light blocking element 134 may include a cut-out profile. FIG. 2A shows an example cut-out profile of the light blocking element 134 of the analog input device 100 according to various embodiments; FIG. 2B and FIG. 2C show example movements of the cut-out profile of the light blocking element 134 of the analog input device 100 according to various embodiments.

The cut-out profile 135 of the light blocking element 134 may vary the amount of light passing through the light blocking element 134 as the light blocking element 134 moves transversely across the light path 131 when a pressure or force is applied to push the button cap 123 towards the at least one mounting panel 110 (i. e. along the movement direction of the plunger element 122). Accordingly, the cut-out profile 135 of the light blocking element 134 may vary the extent of blockage of the light path 131 according to the movement of the plunger element 122 as a result of the pressure or force on the pressure reception arrangement 124. According to various embodiments, the light blocking element 134 may include an elongate plate with the cut-out profile 135 and may be disposed so as to move longitudinally to intersect the light path 131 as the user applies a pressure or force to depress the button cap 123. According to various embodiments, the cut-out profile 135 of the light blocking element 134 may include an elongate shape extending from a lower end 134a to an upper end 134b of the light blocking element 134 and enclosed by a continuous border 135a.

A width between opposing border sections of the border 135a of the cut-out portion 135 along the light path 131 (e.g. perpendicular to the movement direction of the plunger element 122) may gradually increase from the lower end 134a (e.g. an initial passing width denoted as w1 in FIG. 2A) to the upper end 134b of the light blocking element 134 (e.g. a maximum passing width denoted w2 in FIG. 2A) in a manner that the amount of light passing through the light blocking element 134 increases as the light blocking element 134 moves along the movement direction 201 (shown in FIGS. 2B and 2C) from an initial position to a maximum position. In other words, the width between opposing border sections of the border 135a may determine the amount of light passing through the light blocking element 134, e.g. the wider the width between opposing border sections of the border 135a, the larger amount of light passing through the light blocking element 134 and detected by the light sensor 132 for output as a higher (if the analog signal (e.g. analog current) is proportional to the amount of light) or lower (if the analog signal (e.g. analog voltage) is inversely proportional to the amount of light) analog signal. The maximum passing width w2 may be so designed that the amount of light passing through the light blocking element 134 is below the saturation value of the light sensor 132.

In various embodiments, the cut-out profile 135 of the light blocking element 134 may be symmetrical along a longitudinal axis (denoted as 137 in FIG. 2A). The cut-out profile 135 of the light blocking element 134 may be so designed that the amount of light passing through the light blocking element 134 is linearly or exponentially or quadratically increased as the light blocking element 134 moves down (e.g. at a substantially constant speed). For example, the width between opposing border sections of the border 135a of the cut-out portion 135 may gradually increase in a manner that the amount of light passing through the light blocking element 134 increases linearly. For example, the cut-out profile 135 of the light blocking element 134 may be substantially an inversed isosceles triangle shape and the width between opposing border sections of the border 135a may increase linearly.

FIG. 2B shows that the light blocking element 134 is at its initial (default) position when the analog push button assembly 120 is not pressed. When the light blocking element 134 is at the initial position, the light blocking element 134 may allow an initial amount of light to pass through the blocking element 134 (e.g. through the initial passing width w1). Accordingly, when the analog push button assembly 120 is not pressed (e.g. at its default/initial position), the light sensor 132 may detect an initial amount of light incident on the light sensor 132 and output an initial analog signal according to the initial amount of light (e.g. an initial intensity of light) detected.

FIG. 2C shows that the light blocking element 134 is at its maximum position where the analog push button assembly 120 cannot travel any further even if the pressure or force exerted on the analog push button assembly 120 continues to increase (e.g. by some stopping mechanism). When the light blocking element 134 is at the maximum position, the light blocking element may allow a maximum amount of light to pass through the blocking element 134 (e.g. through the maximum passing width w2). Accordingly, when the analog push button assembly 120 is pressed to its maximum position, the light sensor 132 may detect the maximum amount of light incident on the light sensor 132 and output a maximum (if the analog signal is proportional to the amount of light) or minimum (if the analog signal is inversely proportional to the amount of light) analog signal according to the maximum amount of light (e.g. a maximum intensity of light) detected.

Accordingly, as the light blocking element 134 is pressed by the user's finger to move from the initial position as shown in FIG. 2B to the maximum position as shown in FIG. 2C, the amount of light passing through the blocking element 134 (e.g. through the width of opposing border sections of the cut-out profile 135) may gradually increase. Therefore, the light sensor 132 may detect a gradual increase of light incident thereon and output a gradually increased (if the analog signal is proportional to the amount of light) or decreased (if the analog signal is inversely proportional to the amount of light) analog signal. For example, if the amount of light passing through the blocking element 134 (e.g. through a linearly increased width of opposing border sections of the cut-out profile 135) increases linearly, the light sensor 132 may detect a linear increase of light incident thereon and output a linearly increased (if the analog signal is proportional to the amount of light) or decreased (if the analog signal is inversely proportional to the amount of light) analog signal.

Referring back to FIG. 1, according to various embodiments, the analog input device 100 may include a multiplexer 138 having an output side and an input side. According to various embodiments, the input side of the multiplexer 138 may be coupled to the output terminals 133 of the matrix of analog push button assemblies 120. Accordingly, the multiplexer 138 may accept multiple analog signals from the matrix of analog push button assemblies 120 and provide a single output. According to various embodiments, the analog input button assemblies 120 of the analog input device 100 may be coupled to the multiplexer 138 via a matrix connection.

According to various embodiments, the analog input device 100 may include an analog-to-digital converter (ADC) 140. The ADC 140 may be coupled to the output side of the multiplexer 138. Accordingly, the ADC 140 may receive the analog signal from the multiplexer 138 and may be configured to discretize the analog signal into a corresponding digital-step-value. According to various embodiments, the multiplexer 138 may be electrically coupled to the ADC 140 such that the analog signal output from the multiplexer 138 may be sent to the ADC 140 for converting into readable data. According to various embodiments, the ADC 140 may convert the continuous-time and continuous-amplitude analog signal from the multiplexer 138 into a discrete-time and discrete-amplitude digital-step-value. According to various embodiments, the ADC 140 may perform the conversion at a predetermined sampling interval. According to various embodiments, the total number of discrete digital-step-values for the range of analog signal from the light sensor 132 may be based on a resolution of the ADC 140. According to various embodiments, the digital-step-value may be an integer number from 0 to N, whereby N is one less than a power of two. Accordingly, each integer number of the digital-step-value may represent a corresponding magnitude of the analog signal from the light sensor 132.

According to various embodiments, the analog input device 100 may include a processor 142. The processor 142 may be coupled to the ADC 140 in a manner so as to receive the digital-step-value. The processor 142 may be configured to output a data packet including a button identity (ID) of the push button assembly 120 pressed by the user's finger and the digital-step-value corresponding to the analog signal from the push button assembly 120. According to various embodiments, the processor 142 and the ADC 140 may be in digital communication with each other. Accordingly, the digital-step-value converted by the ADC 140 may be digitally communicated to the processor 142 from the ADC 140. According to various embodiments, the processor 142 may receive various information data from the ADC 140 and/or the pressure reception arrangement 124 and/or the pressure sensor 121, and may arrange, compile and/or format the various information data, including button identity (ID) and the digital-step-value, into a string of formatted data for transmission. According to various embodiments, the string of formatted data may be in the form of a USB (Universal Serial Bus) HID (Human Interface Device) Vendor report.

According to various embodiments, the analog input device 100 may include a communication interface 144. The communication interface may be wired or wireless. The communication interface 144 may be connectable to a host computing device. The communication interface 144 may be configured to transmit the data packet from the processor 142 to the host computing device. According to various embodiments, the wired communication interface 144 may include USB connector or multi-pin electrical connectors. According to various embodiments, the wireless communication interface 144 may include infrared (IR) communication interface, radio frequency (RF) communication interface, Bluetooth communication interface, or Wi-Fi communication interface. According to various embodiments, the host computing device may be a computer or a programmable machine or programmable electronic device to which peripherals such as the input device 100 may be connected to and which directs the operation of the peripherals, including drivers for input/output devices connected to the host computing device.

According to various embodiments, the ADC 140 and the processor 142 may be separate elements of the analog input device 100. According to various embodiments, the ADC 140 and the processor 142 may be integrated as a single microcontroller 150.

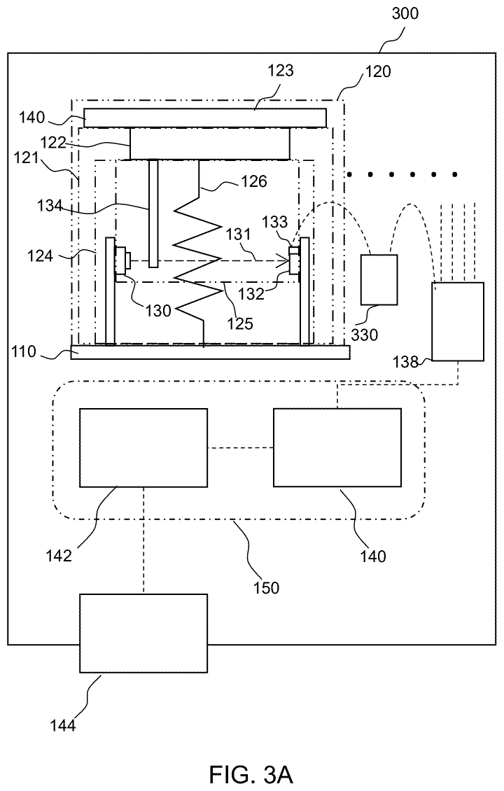

FIG. 3A shows a schematic diagram of an analog input device 300 according to various embodiments. According to various embodiments, the analog input device 300 of FIG. 3A includes all the features of the analog input device 100 of FIG. 1. Accordingly, all features, changes, modifications, and variations that are applicable to the analog input device 100 of FIG. 1 may also be applicable to the analog input device 300 of FIG. 3A. According to various embodiments, the analog input device 300 of FIG. 3A may differ from the analog input device 100 of FIG. 1 in that the analog input device 300 of FIG. 3A may further include the following additional features and/or limitations.

According to various embodiments, the analog input device 300 of FIG. 3A may further include digital potentiometers 330 (also known as digital resistors). Digital potentiometers are integrated circuit (ICs). Some variants have a non-volatile memory (e. g., EEPROM or Flash) which remembers the potentiometer resistance setting. Because of their relatively small size compared to conventional potentiometers, multiple potentiometers can be packed on a single chip. Digital potentiometer ICs with a plurality of channels are available.

The digital potentiometers 330 may be coupled in an electrical connection between the matrix of analog input button assemblies 120 and the multiplexer 138. In some embodiments, each digital potentiometer 330 may be coupled to the output terminal 133 of the pressure reception arrangement 124. In some embodiments, each digital potentiometer 330 may be coupled to several output terminals 133 of the pressure reception arrangements 124, e. g. each channel of the digital potentiometer 330 coupled to the output terminal 133 of one pressure reception arrangement 124. The digital potentiometers 330 may be configured to be tunable in values (e. g. resistance) so as to adjust the output analog signals (e. g. analog voltages). The digital potentiometers 330 may be controlled by a microcontroller (e. g. the processor 142). The digital potentiometers 330 may be calibrated by software commands which also may be configured to detect faulty switches and foreign material clogging the light path (e. g. the light path 131). The digital potentiometers 330 may be tunable in a manner that the analog voltages are substantially linearly and inversely proportional to a travel distance of the light blocking element 134.

It should be appreciated that the digital potentiometers 330 may also be tunable in a manner that the analog voltages are substantially linearly and proportional to a travel distance of the light blocking element 134. In an example, the width between opposing border sections of the border 135a of the cut-out portion 135 may gradually decrease in a manner that the amount of light passing through the light blocking element 134 decreases linearly, and consequently the analog voltages may be substantially linearly and proportional to a travel distance of the light blocking element 134. In an example, as the amount of light passing through the light blocking element 134 and detected by the light sensor 132 for output increases and if the analog voltage signal is proportional to the amount of light detected, the analog voltage increases.

FIG. 3B shows a graph 305 of voltage changes with travel distances of the light blocking element 134 of the analog input device 300 according to various embodiments. The y-axis represents the voltages (V) 301 and the x-axis represents the travel distances (mm) 303 of the light blocking element 134. The voltages may be recorded from the ADC 140. The graph 305 shows the voltage is inversely proportional to the travel distance of the light blocking element 134. Specifically, the graph 305 shows at the initial position where the travel distance 303 of the light blocking element 134 is zero (e.g. the button cap is not pressed), i.e. the amount of light (e.g. intensity) detected by the detector 132 is at its minimum but not zero, the voltage 301 is at its maximum. As the travel distance 307 of the light blocking element 134 increases from zero to a maximum (denoted as 307, approximately equal to 4 mm or greater than 4 mm), i.e. the amount of light (e.g. intensity) detected by the detector 132 increase to its maximum, the voltage 301 substantially linearly decreases to its minimum.

According to various embodiments, the analog input device 300 of FIG. 3A may further include a filter (not shown). The filter may be coupled in an electrical connection between the pressure sensor 121 and the analog-to-digital converter 140. The filter may be configured to reduce noise in the analog signal from the pressure sensor 121. According to various embodiments, the filter may include a low-pass filter.

According to various embodiments, the analog input device 300 of FIG. 3A may further include a storage element (not shown). The storage element may be coupled to the processor 142 and may store instructions for execution by the processor 142. According to various embodiments, the storage element may be a memory. According to various embodiments, the memory may include, but not limited to, a read-only memory (ROM), an erasable programmable read-only memory (EPROM), or a flash memory.

According to various embodiments, the analog input device 300 of FIG. 3A may further include a lighting arrangement (not shown) including at least one light source controlled by the processor 142. According to various embodiments, the lighting arrangement may include backlighting for the at least one analog input button assembly 120, and/or underglow lighting for the analog input device 300. Hence, the at least one light source may serve as backlight for the at least one analog input button assembly 120 and/or may serve as underglow light for the analog input device 300.

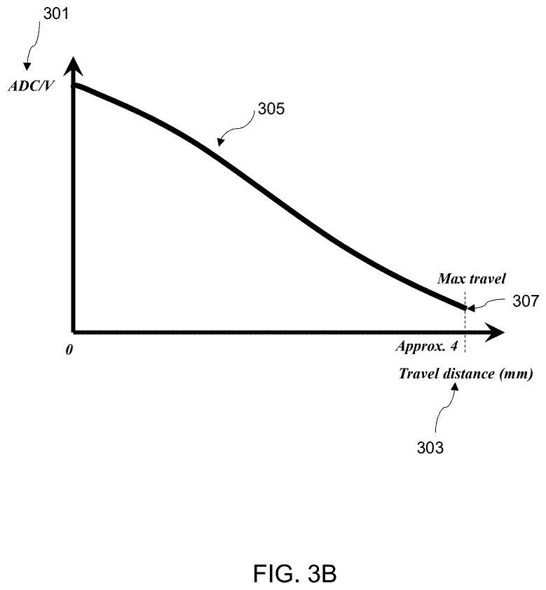

FIG. 4 shows a schematic diagram of a computing system 401 for receiving and processing analog input (e.g. analog output from the output terminal 133 of the analog input device 100 of FIG. 1, analog output from the digital potentiometers 330 of the analog input device 300 of FIG. 3A) according to various embodiments. According to various embodiments, the computing system 401 may include a host processor 402 and the analog input device 100, 300 (of FIGS. 1 and 3A respectively) connected to the host processor 402 via the communication interface 144. According to various embodiments, the host processor 402 may be a central processing unit of the host computing device 404. According to various embodiments, the host processor 402 may receive the data packet from the input device 100, 300. According to various embodiments, the host processor 402 may interpret the input data packet from the input device 100, 300 and execute programed instructions based on the interpreted input data packet. According to various embodiments, the host processor 402 may determine an amount of depression of the button cap 123 of a respective push button assembly 120 based on the digital-step-value corresponding to the analog signal from the push button assembly 120. According to various embodiments, the host processor 402 may determine an amount of depression of the button cap 123 of the respective push button assembly 120 via performing calculation or mathematical processing or mapping or table loop-up operation or other suitable processing technique. According to various embodiments, the host processor 402 may generate a corresponding predetermined application event in an application program based on the determined amount of depression of the button cap 123 of the respective push button assembly 120 and an input setting for the application program. According to various embodiments, the corresponding predetermined application event may be a programmed action or occurrence triggered by the application program in response or recognition of the determined amount of depression of the button cap 123 of the respective push button assembly 120. According to various embodiments, the input setting for the application program may be a mapping of predetermined application events to the matrix of analog push button assemblies 120 and respective amount of depression. According to various embodiments, the input setting may be a pre-defined setting in the application program. According to various embodiments, the input setting may be a user definable or configurable setting which the user may alter or change in the application program accordingly based on user preference and usage.

According to various embodiments, the host processor 402 may be further configured to transform the determined amount of depression of the button cap 123 of the respective push button assembly 120 onto a non-linear scale prior to generating the corresponding predetermined application event. According to various embodiments, the non-linear scale may include a logarithmic scale or a variable scale. According to various embodiments, with the translation of the determined amount of depression of the button cap 123 of the respective push button assembly 120 onto the non-linear scale, the analog input device 100 may be configured to be more responsive in the lower or middle or higher depression range. According to various embodiments, translation to non-linear scale may allow the user to customise their own setting to suit their personal usage based on desired responsiveness of the analog input device 100.

According to various embodiments, the corresponding predetermined application event may include a continuous variable action. For example, in gaming, the continuous variable action may include a magnitude for a character's speed, directions, movements, actions etc, According to various embodiments, the host processor may be configured to generate a state of the continuous variable action according to the determined amount of depression of the button cap 123 of the respective push button assembly 120.

According to various embodiments, the corresponding predetermined application event may include a discrete action. For example, the discrete action may be a binary action such as on or off. According to various embodiments, the host processor may be configured to generate the discrete action when the determined amount of depression of the respective push button assembly 120 is equal to or greater than a pre-set depression level of the respective push button assembly 120. Accordingly, the input device may serve as a normal binary input device such as a type-writing keyboard or a numeral keypad etc. According to various embodiments, with the pre-set depression level of the button cap 123 of the respective push button assembly 120, an actuation point or trigger point of the respect push button assembly 120 may be configured or programmed. Accordingly, the respective push button assembly 120 may be configured or programmed to generate the discrete action at a desired amount of depression. Thus, the respective push button assembly 120 may trigger the discrete action without requiring full depression of the button cap 123 of the push button assembly 120. According to various embodiments, the pre-set depression level of the button cap 123 of the respective push button assembly 120 may be a user defined input. Accordingly, the host processor 302 may be configured to receive and store the user defined input as the pre-set depression level of the button cap 123 of the respective push button assembly 120.

According to various embodiments, the corresponding predetermined application event may include a first discrete action and a second discrete action. According to various embodiments, the host processor may be configured to generate the first discrete action when the determined amount of depression of the button cap 123 of the respective push button assembly 120 is equal to a first pre-set depression level of the button cap 123 of the respective push button assembly 120 or between the first pre-set depression level of the button cap 123 of the respective push button assembly 120 and a second pre-set depression level of the button cap 123 of the respective push button assembly 120. According to various embodiments, the host processor may be configured to generate the second discrete action when the determined amount of depression of the button cap 123 of the respective push button assembly 120 is equal to or greater than the second pre-set depression level of the button cap 123 of the respective push button assembly 120. Accordingly, a single push button assembly 120 may be configured to trigger to two or more different discrete actions by pre-setting the two or more different depression ranges for triggering the respective discrete actions. According to various embodiments, each of the first and second pre-set depression levels of the button cap 123 of the respective push button assembly 120 may be a respective user defined input. Accordingly, the host processor 402 may be configured to receive and store the user defined inputs as the first and second pre-set depression levels of the button cap 123 of the respective push button assembly 120.

According to various embodiments, the host processor may be configured to toggle between a first input setting and a second input setting for the application based on a user input command via a physical modifier key or a virtual modifier key. According to various embodiments, a first corresponding predetermined application event associated with the first input setting may be different from a second corresponding predetermined application event associated with the second input setting. For example, in gaming, the first input setting may be a first mapping of fighting related predetermined application events to the matrix of analog push button assemblies 120 and the second input setting may be a second mapping of driving related predetermined application events to the matrix of analog push button assemblies 120.

In the following, a gaming keypad is described as an example of the analog input device 100, 300 according to the various embodiments.

A gaming keypad combines the benefits of keyboards with the compact and ergonomic size of a controller. Typical gaming keypads contain 15-25 keys designed to be controlled by fingers of the users. These keys are laid out in a way similar to that of a keyboard's number pad, to realize various functions such as directions and navigations (up, down, left, and right), changing a weapon, jumping, or shooting. However, the keys in the conventional keypad are coupled to digital switches, which only output a binary signal, limiting the achievable functions of the keypad and possible user intents.

Example embodiments solve these problems by employing analog switches that output analog signals and a corresponding algorithm that process the signals sent from individual keys of the keypad at the host computer that is connected with the keypad wirelessly or through a USB. Analog keypads provide an enhanced input method with more granularity which gives mechanical keyboards the precision control normally found in devices such as gaming controllers, steering wheels, and aviation joysticks. By processing the signals from each key at the host computer, the latency is reduced, and a quicker response is achieved. Further, upgrading the processing solution by handling it in software offers the user flexibility in key mapping. In addition, lighting up the keypad based on the amount of depression of the individual keys may provide visual feedback or indicator to the user. Accordingly, the keypad may display the amount of depression of the individual keys through lighting effects that are proportional to the amount of depression.

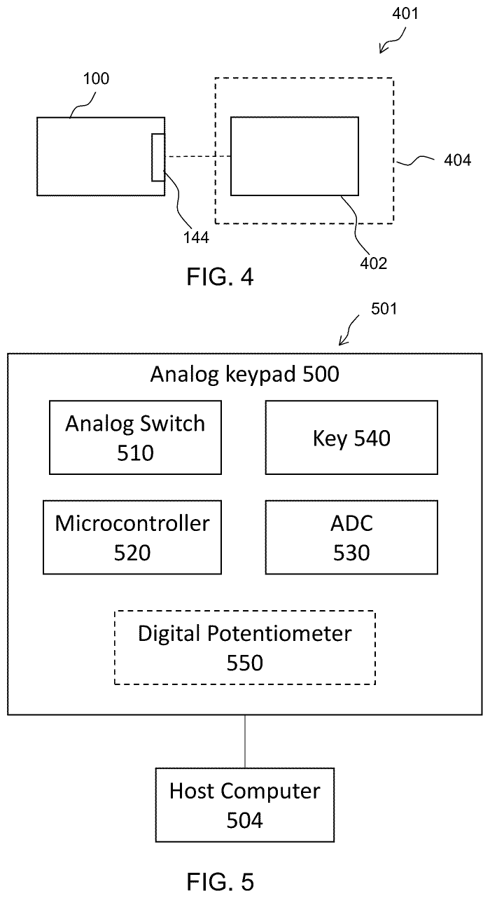

FIG. 5 shows a computing system 501 having an analog keypad 500, as an analog input device, in accordance with an example embodiment.

By way of example, the analog keypad 500 may include a plurality of analog switches 510 (or analog pressure sensor) each disposed under a key 540, a microcontroller 520 that includes a processor and a memory, and an analog-to-digital converter (ADC) 530. The analog switches 510 may be based on opto-mechanical switch technology and output different analog signals according to the pressure or force applied to the keys or the displacement of the keys compared with the un-pressed position. The ADC 530 may convert the analog signals into digital signals and send the digital signals to the microcontroller 520 to preprocess the data. In some embodiments, the analog keypad 500 may optionally include digital potentiometers 550 and, accordingly, the output from the analog switches 510 may be adjusted by the digital potentiometers 550 prior to inputting to the ADC 530. The adjusted analog signals may be (inversely) linearly proportional to an amount of depression of the key 540. The ADC 530 may subsequently convert the adjusted analog signals into digital signals and send the digital signals to the microcontroller 520 to preprocess the data.

The analog keypad 500 may be connected with a host computer 504 wirelessly or through a USB. The host computer 504 may receive the preprocessed data from the microcontroller and perform calculation to determine the pressure or force applied to one or more keys and proceed with actions to be taken by a host processor (not shown) of the host computer 504. According to various embodiments, host processor (not shown) of the host computer 504 may proceed with a particular action (e.g. a character moving at a certain magnitude of speed which corresponds to a certain amount of depression of the key 540).

Firmware may be held in the memory (or storage element) such as ROM, EPROM, or flash memory, in order to provide control for the switches and translate the analog signals sent from each analog switch to the hosting computer, such that the hosting computer may further process the signals or data to realize the corresponding functions.

In one example embodiment, when the user presses a key (or a button assembly) to a specific distance, the firmware may register this event and the event will be read by the microcontroller. Different events may be registered for difference distances the keys are pressed down. This microcontroller may constantly be monitoring the keys on the keypad via scanning, which may occur many times per second. The firmware may register when the key is pressed and to what distance the key is pressed, and rapidly perform the process of translating the keypresses from physical contact into electrical signals and then outputting them to the host computer for proportionally (e. g. linearly) controlling a corresponding predetermined application event.

By way of example, one analog switch (or pressure sensor) may reside underneath each key. The analog switch may include a light emitter, a chopper (or a light blocking element) disposed in the light path and a light receiver (or light sensor). The path that the lights travels along may be substantially in parallel to the surface of the keycap (or button cap). The amount of light that may be detected by the light receiver may be affected by the location of the chopper, which may be further determined by how far the key is pressed down as a function of pressure or force applied to the keycap. As the displacement of the key is proportional to the pressure or force applied, and the amount of light passing through the chopper may be related to the displacement of the key, the amount of the light detected by the light receiver may also be related to the pressure or force applied to the key. As such, the amount of light indicates the pressure or force applied on the key. For example, a spring (or a biasing element) under the key may be configured to allow a displacement of the keycap from the top end position to a bottom end position, which is proportional to the pressure or force applied to the key. The light receiver outputs analog data based on the intensity of the light detected and the analog data is further processed by the microcontroller before being sent to the host computer for proportionally (e.g. linearly) controlling a corresponding predetermined application event.

In one example embodiment, when two directional keys representing x and y directions, respectively, are pressed down simultaneously, the analog switch underneath the first key may output a first analog signal having a first magnitude (e. g. (inversely) linearly proportional to the travel distance of the first direction key representing x), and the analog switch underneath the second key may output a second analog signal having a second magnitude (e. g. (inversely) linearly proportional to the travel distance of the second direction key representing y). The ADC converts the first and second magnitudes, which are analog signals, into digital signals based on a calibration set with a predetermined range of numbers with a minimum value and a maximum value, and sends the digital signals to the microcontroller.

The microcontroller may further process the digital signals sent by the ADC and converts the digital signals to codes (or format) that the host computer can understand. For example, when the analog keypad is connected with the host computer through USB, the converted code is a USB code. The conversion is usually done using a lookup table. This table is also where the keyboard layout is defined. The host computer receives the codes of each key from the analog keypad and calculates the addition of the codes, for example, and then determine the directions of the movement. The host computer may further adjust the actuation point of the switches. In addition, the host computer may change the function of the key based on the amount of pressure or force applied on the keycap.

The above-mentioned analog keypad 500 is shown as one example embodiment of an input device. Other input devices such as mice, keyboards or controller with analog switches also apply. One or more features of the input device other than computer games may advantageously be incorporated for many other applications in translating user intent to a form interpretable by any type of computing device, including, but not limited to, personal computers, entertainment systems, industrial computing systems, stenography devices, medical computing systems, and other computing devices.

Automatic calibration of the input devices according to various embodiments may be conducted by manufacturers in factory lines, to overcome systemic deviation which includes, but not limited to Optical Switch Driver (OSD) deviation, infrared (IR) . . . photo transistor (PT) deviation, surface-mount technology (SMT) soldering quality, assembly error etc. The calibration may include the Printed Circuit Board Assembly (PCBA) self-testing including manual IRPT testing and OSD self-testing.

The IRPT testing may be conducted to ensure uniformity of IRPT components, and to identify any IRPT SMT soldering issue. To conduct IRPT testing, operator may put the PCBA to a big box that blocks any light outside, and then press the button in the calibration software to send sampling times n and notify to the keyboard firmware to start IRPT testing. The keyboard firmware may turn on IR and sampling n times key by key to avoid light interference, then send an average and range of the calibration results to the calibration software. The calibration software may send pass to the keyboard firmware if the average and range of the calibration results meet the thresholds, and the keyboard firmware may save the average and range of the calibration results as benchmark for future testing. If the average and range of the calibration results does not meet the thresholds, the calibration software may send fail to the keyboard firmware, and show failure in the calibration software.

The calibration may cover a whole key-travel of 0-4.5 mm by pressing a key under test using a fixture to the top (e.g. the position of the key as shown in FIG. 2B), middle and bottom (e.g. the position of the key as shown in FIG. 2C) positions of the key. The middle position of the key may be a position in between the top position of the key and the bottom position of the key, e.g. a middle position at a distance substantially equally from the top and bottom positions of the key. Calibration software may read luminous flux from the OSD sensor (e.g. the amount of light passing through the light blocking element 134 and detected by the light sensor 132) of the fixed top, middle and bottom positions to determine proper IR current and active time for each OSD sensor.

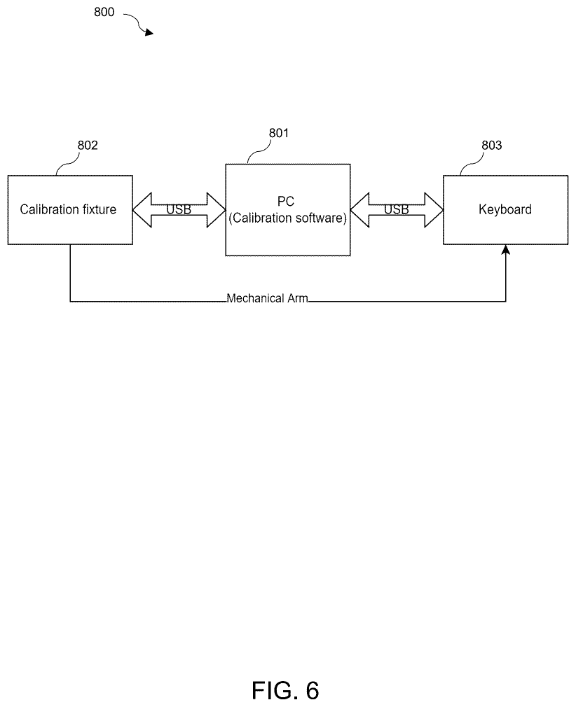

FIG. 6 shows a calibration system 800 implemented by the input devices according to various embodiments. The calibration system 800 may include a calibration software 801, a calibration fixture 802 and a keyboard firmware 803. The calibration software 801 may be configured to run on a personal computer. The calibration fixture 802 may include a mechanical arm configured to press a key under test. The keyboard firmware 803 may be programmed into a memory of a keyboard. The calibration fixture 802 and the keyboard firmware 803 may be connected to the calibration software 801 via USB interfaces or wirelessly connected. The calibration system 800 may be used (e.g. by manufactures at factories) to do online calibration, e.g. OSD self-testing.

The OSD self-testing may be conducted to identify OSD hardware issues by a keyboard-firmware-embedded routine at each time of power-on reset (POR). The OSD self-testing may run automatically at POR. The OSD (e.g. a small IC) may be disposed under every key of the keyboard. The keyboard firmware (e.g. 803) may report an error to a user interface (UI) application when an OSD hardware issue (e.g. component fault) or SMT rosin joint detected by the OSD self-testing, to help sustaining or service teams locating the root cause quickly. The keyboard firmware may report an error code with extra bytes of the key position (to locate the failed OSD) to the calibration software (e.g. 801) if there is OSD hardware issue (e.g. component fault) or SMT rosin joint. An OSD error may be a critical hardware fault which causes firmware struck and disables all functionality. The keyboard firmware (e.g. 803) may always report a first error of key position if there are several keys with OSD hardware issues, as the OSD test may be stopped by the firmware when the first OSD error is found. The keyboard firmware (e.g. 803) may continue running the OSD self-testing routines until all the hardware errors are fixed. The keyboard firmware (e.g. a main microcontroller unit (MCU) of 803) may send command code 0xA0 or 0xA1 to an analog MCU of the calibration software (e.g. 801), determine if there is hardware error based on a return value 0xC4 from the analog MCU of the calibration software (e.g. 801), and then report the key position if there is an hardware error. Once the OSD hardware error is reported, the keyboard may be disabled and light the corresponding key having the hardware error in red as error indication. The calibration may not reach saturation voltage during the whole-key travel and may not exceed 5% deviation during the whole-key travel when keys are pressed to the end (e.g. the bottom position of the key).

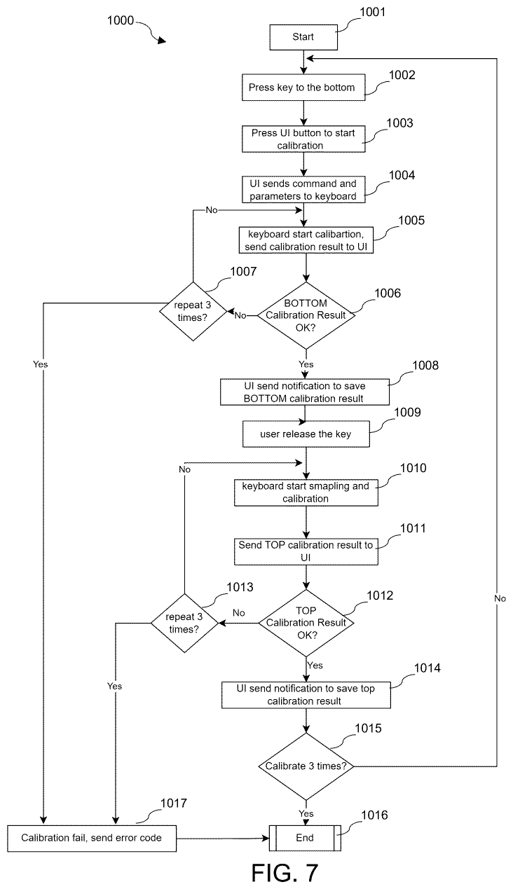

FIG. 7 shows a flowchart of the user calibration process 1000 of the input devices according to various embodiments. The user calibration process 1000 may be repeated a number of times for each calibration, for example, three times as described herein. It should be appreciated that the user calibration process 1000 may be repeated any number of times according to requirements, for example, one time (i.e. no repeat) or four times.

At step 1001, the user calibration process 1000 starts.

At step 1002, the user is guided to press and hold a key to the bottom position of the key. Accordingly, the key that is pressed and held by the user is the key under test.

At step 1003, the user is guided to press a UI button displayed on the personal computer on which the calibration software runs to start the user calibration process 1000.

At step 1004, the UI (e.g. the calibration software running on the personal computer) sends command and parameters to the keyboard firmware.

At step 1005, the keyboard firmware starts calibration and sends the calibration results of the bottom position of the key under test to the UI.

At step 1006, the calibration software determines if the calibration results of the bottom position of the key under test are OK. That may mean the calibration software determines if the calibration results of the bottom position meet certain criteria (e.g. thresholds) that is pre-programmed to the calibration software. If the calibration results of the bottom position of the key under test are not OK, the user calibration process 1000 proceeds to step 1007. If the calibration results of the bottom position of the key under test are OK, the user calibration process 1000 proceeds to step 1008.

At step 1007, the calibration software determines if the user calibration process 1000 has been repeated three times. If no, the user calibration process 1000 goes back to the step 1005 by repeating the steps 1005 and 1006. If yes, the user calibration process 1000 goes to the step 1017, the calibration fails and the calibration software sends an error code.

At step 1008, the UI sends notification to save the calibration results of the bottom position of the key under test.

At step 1009, the user is guided to release the key that the user has been pressing. Accordingly, the key that is released by the user is the key under test.

At step 1010, the keyboard firmware starts calibration and sends calibration results of the top position of the key under test to the UI.

At step 1011, the keyboard firmware sends calibration results of the top position of the key under test to the UI.

At step 1012, the calibration software determines if the calibration results of the top position are OK. If the calibration results of the top position are not OK, the user calibration process 1000 proceeds to step 1013. If the calibration results of the top position are OK, the user calibration process 1000 proceeds to step 1014.

At step 1013, the calibration software determines if the user calibration process 1000 has been repeated three times. If no, the user calibration process 1000 goes back to the step 1010 by repeating the steps 1010 and 1011 three times. Otherwise, the user calibration process 1000 goes to the step 1017, the calibration fails and the calibration software sends an error code.

At step 1014, the UI sends notification to save the calibration results of the top position.

At step 1015, the calibration software determines if the calibration process 1000 has been performed three times. If no, the user calibration process 1000 goes back to the step 1001 and repeat the user calibration process 1000 (e.g. for the second or third time of the calibration process); if yes, the user calibration process 1000 goes to step 1016 and user calibration process 1000 ends.

While the process 900, 1000 described above is illustrated and described as a series of steps or events, it will be appreciated that any ordering of such steps or events are not to be interpreted in a limiting sense. For example, some steps may occur in different orders and/or concurrently with other steps or events apart from those illustrated and/or described herein. In addition, not all illustrated steps may be required to implement one or more aspects or embodiments described herein. Also, one or more of the steps depicted herein may be carried out in one or more separate acts and/or phases.

According to various embodiments, there is provided an input device for providing inputs to a computing device. The input device may include at least one input key or button. The at least one input key or button may include an input surface to receive a depressing force or pressure applied by a user. The at least one input key or button may include a switch interaction component to interact with an analog switch. The at least one input key or button may include the analog switch to receive an interaction with the interaction component, whereby the analog switch detects a property that is a function of the amount of depressing force or pressure applied by the user.

According to various embodiments, the input device may be a keyboard having a plurality of input keys, or a keypad having a plurality of input keys, or a mouse having two or more click buttons, or a game controller having a plurality of input keys or buttons.

According to various embodiments, the input surface may be a keycap on the top surface of the key and the switch interaction component may be attached to the bottom surface of the key.

According to various embodiments, the analog switch may be located underneath the key and may interface with the switch interaction component that is attached to the bottom surface of the key.

According to various embodiments, the switch may include a light emitter, light receiver, and a chopper, whereby the light emitter may emit light in a light path substantially in parallel to the surface of the keycap which is received by the light receiver, wherein the chopper may be disposed between the light emitter and light receiver.

According to various embodiments, the interaction component may be configured to interface with the chopper to cause the chopper to move within the light path and affect the amount of light that passes through the chopper and that is received by the light receiver, and wherein the property detected by the analog switch is an amount of light received by the light receiver.

According to various embodiments, the amount of movement of the chopper within the light path may be a function of the amount of depressing force or pressure applied by the user.

Various embodiments have provided an analog input device which may provide more granularity of the input in an effective and simple manner. Various embodiments have also provide an analog input device whereby the data processing will be done by the host computing device while the analog input device will just send analog data. In other words, major data crunching is performed by the host computing device while the analog input device only perform minimum pre-processing of analog signal for sending to the host computing device. Accordingly, manufacturing costs of the analog input device may be significantly reduced and the analog data processing performance may increase. Various embodiments have provided an analog input device which has re-defined conventional input device. According to various embodiments, the analog input device may give more option to end user. According to various embodiments, the analog input device of the computing system may provide definable trigger point (or configurable actuation point), more than one trigger point which allows multi-functions with a single key (or multiple actuation point for multiple events with a single key/button), and/or joystick/flight stick/driving wheel/game controller functions mapping.

While the invention has been particularly shown and described with reference to specific embodiments, it should be understood by those skilled in the art that various changes, modification, variation in form and detail may be made therein without departing from the scope of the invention as defined by the appended claims. The scope of the invention is thus indicated by the appended claims and all changes which come within the meaning and range of equivalency of the claims are therefore intended to be embraced.

1. An analog input device comprising:
a mounting panel;
a matrix of analog push button assemblies mounted to the mounting panel, each analog push button assembly comprising an analog pressure sensor, wherein the analog pressure sensor comprises:
a plunger element; and
a pressure reception arrangement having an optical sensing sub-arrangement and an output terminal,
wherein when the analog push button assembly is pressed by a user's finger, the plunger element is configured to move towards the mounting panel to exert a pressure on the pressure reception arrangement,
wherein the optical sensing sub-arrangement comprises a light blocking element which is associated with the plunger element in a manner so as to be movable together with the plunger element along a movement direction of the plunger element, and the light blocking element comprises a cut-out profile which varies an amount of light passing through the light blocking element as the light blocking element moves along the movement direction, and
wherein the pressure reception arrangement is configured to measure the amount of light passing through the light blocking element and output an analog signal corresponding to the amount of light measured through the output terminal.

2. The input device as claimed in claim 1, wherein the light blocking element is configured to move from an initial position to a maximum position along the movement direction together with the plunger element corresponding to the depression of the push button assembly by the user's finger.

3. The input device as claimed in claim 2, wherein when the analog push button assembly is not pressed and the light blocking element is at the initial position, the light blocking element allows an initial amount of light to pass through the blocking element.

4. The input device as claimed in claim 3, wherein the light blocking element comprises a cut-out portion, and the cut-out portion has an elongate shape extending from a lower end to an upper end of the light blocking element and enclosed by a continuous border.

5. The input device as claimed in claim 4, wherein a width between opposing borders of the cut-out portion along a direction perpendicular to the movement direction of the plunger element gradually increases from the lower end to the upper end of the light blocking element in a manner that the amount of light passing through the light blocking element increases as the light blocking element moves along the movement direction from the initial position to the maximum position, and
wherein the width between opposing borders of the cut-out portion gradually increases in a manner that the amount of light passing through the light blocking element increases linearly, or wherein when the light blocking element moves from the initial position to the maximum position, the width between opposing borders of the cut-out portion increases from an initial width allowing the initial amount of light passing through the blocking element to a maximum width.

6. (canceled)

7. (canceled)

8. (canceled)

9. The input device as claimed in claim 1, wherein the optical sensing sub-arrangement further comprises:
a light emitter oriented to emit light along a light path perpendicular to the movement direction; and
a light sensor which is disposed in the light path and which is configured to generate the analog signal based on the amount of light sensed by the light sensor for outputting via the output terminal,
wherein the light blocking element moves transversely across the light path when the plunger element is moved towards the mounting panel.

10. (canceled)

11. The input device as claimed in claim 1 further comprising:
a digital potentiometer,
wherein the digital potentiometer is coupled in electrical connection with the matrix of analog push button assemblies and tunable with respect to its resistance,
wherein the analog signal is an analog voltage, and
wherein the analog voltage is in inverse proportion with the amount of light passing through the light blocking element, or wherein the digital potentiometer is tunable in a manner that the analog voltage is linearly proportional to a travel distance of the light blocking element.

12. (canceled)

13. (canceled)

14. (canceled)

15. The input device as claimed in claim 1, further comprising:
a multiplexer including an input side and an output side, wherein the input side is coupled to the output terminals of the matrix of analog push button assemblies;
an analog-to-digital converter which is coupled to the output side of the multiplexer;
a processor which is coupled to the analog-to-digital converter and which is configured to output a data packet including a button identity (ID) of the push button assembly pressed by the user's finger and a digital-step-value corresponding to the analog signal from the push button assembly; and
a communication interface configured to transmit the data packet to a host computing device,
the input device further comprising an analog filter coupled in an electrical connection between the pressure sensor and the analog-to-digital converter and/or a lighting arrangement including at least one light source controlled by the processor.

16. (canceled)

17. (canceled)

18. The input device as claimed in claim 1, wherein the pressure reception arrangement comprises a biasing element which is arranged between the plunger element and the mounting panel and which biases the plunger element away from the mounting panel in a biasing direction.

19. A computing system for receiving and processing analog input, the computing system comprising:
a host processor; and
the input device according to claim 1 connected to the host processor via a communication interface,
wherein the host processor is configured to receive a data packet from the input device, to determine an amount of depression of a respective push button assembly based on a digital-step-value corresponding to the analog signal from the push button assembly, and to generate a corresponding predetermined application event in an application based on the determined amount of depression of the respective push button assembly and an input setting for the application.

20. The computing system as claimed in claim 19, wherein the host processor is further configured to transform the determined amount of depression onto a non-linear scale prior to generating the corresponding predetermined application event.

21. The computing system as claimed in claim 19, wherein the corresponding predetermined application event comprises a continuous variable action, and wherein the host processor is configured to generate a state of the continuous variable action according to the determined amount of depression.

22. (canceled)

23. The computing system as claimed in claim 19, wherein the corresponding predetermined application event comprises a first discrete action and a second discrete action, and wherein the host processor is configured to generate the first discrete action when the determined amount of depression is equal to a first pre-set depression level or between the first pre-set depression level and a second pre-set depression level, and to generate the second discrete action when the determined amount of depression is equal to or greater than the second pre-set depression level.

24. The computing system as claimed in claim 19, wherein the host processor is configured to toggle between a first input setting and a second input setting for the application based on a user input command via a physical modifier key or a virtual modifier key, and wherein a first corresponding predetermined application event associated with the first input setting is different from a second corresponding predetermined application event associated with the second input setting.

25. A method of processing analog input for a computing system, wherein the computing system comprises a host processor and the input device according to claim 1 connected to the host processor via a communication interface, the method comprising:
generating, via the pressure reception arrangement, the analog signal corresponding to the amount of light measured as a measure of the pressure exerted on the pressure reception arrangement when the push button assembly is pressed by a user's finger;
digitizing, via an analog-to-digital converter of the input device, the analog signal into a corresponding digital-step-value;
outputting, via a processor of the input device, which is coupled to the analog-to-digital converter, a data packet including a button identity (ID) of the push button assembly pressed by the user's finger and a digital-step-value corresponding to the analog signal from the push button assembly;
transmitting, via the communication interface, the data packet from the processor of the input device to the host processor of the computing system;
determining, via the host processor, an amount of depression of the respective push button assembly based on the corresponding digital-step-value from the data packet received; and
generating, via the host processor, a corresponding predetermined application event in an application based on the determined amount of depression of the respective push button assembly and an input setting for the application.

26. The method as claimed in claim 25, further comprising calibrating a tunable digital potentiometer of the input device, via the processor, by pressing the analog push button assembly until the light blocking element reaches a maximum position.

27. The method as claimed in claim 25, further comprising transforming the determined amount of depression onto a non-linear scale prior to generating the corresponding predetermined application event.

28. The method as claimed in claim 25, wherein the corresponding predetermined application event comprises a continuous variable action, and wherein generating the corresponding predetermined event comprises generating a state of the continuous variable action according to the determined amount of depression.

29. The method as claimed in claim 25, wherein the corresponding predetermined application event comprises a discrete action, and wherein generating the corresponding predetermined event comprises generating the discrete action when the determined amount of depression is equal to or greater than a pre-set depression level.

30. (canceled)

31. The method as claimed in claim 25, further comprising toggling between a first input setting and a second input setting for the application based on a user input command via a physical modifier key or a virtual modifier key, and wherein a first corresponding predetermined application event associated with the first input setting is different from a second corresponding predetermined application event associated with the second input setting.

32. (canceled)

33. (canceled)
